(19) United States
(12) Patent Application Publication
(10) Pub. No.: US 2026/0372164 A1
(43) Pub. Date: Nov. 19, 2026

(54) SEMICONDUCTOR DEVICE AND FORMING METHOD OF THE SAME

(71) Applicant: Taiwan Semiconductor Manufacturing Company, Ltd., Hsinchu (TW)

(72) Inventors: Chia-Hsin Lee, Hsinchu City (TW); Chien-Ming Lai, Tainan City (TW)

(73) Assignee: Taiwan Semiconductor Manufacturing Company, Ltd., Hsinchu (TW)

(21) Appl. No.: 19/207,393

(22) Filed: May 14, 2025

(51) Int. Cl. H10W 72/90; H10W 72/00; H10W 90/00

(52) U.S. Cl. CPC H10W 72/90; H10W 72/019; H10W 72/01938; H10W 72/01953; H10W 72/923; H10W 72/934; H10W 72/942; H10W 90/792

(57) ABSTRACT

A semiconductor device includes a conductive feature, a first passivation layer, a metal-insulator-metal (MIM), a conductive via, a conductive pad and a second passivation. The first passivation layer is disposed over the conductive feature and exposes the conductive feature. The MIM structure is disposed in the first passivation layer. The conductive via is disposed in the first passivation layer to electrically connect to the conductive feature, and the conductive via has a first surface facing the conductive feature and a first sidewall facing the first passivation layer. A first angle formed between the first surface and the first sidewall is in a range from 95 degrees to 110 degrees. The conductive pad is disposed over the first passivation layer and the conductive via and electrically connected to the conductive via. The second passivation layer is disposed over the conductive pad.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area. As the demand for miniaturization, higher speed and greater bandwidth, as well as lower power consumption and latency has grown recently, there has grown a need for smaller and more creative packaging techniques of semiconductor dies. Currently, semiconductor packages (e.g., System-on-Integrated-Circuit (SoIC) components) are becoming increasingly popular for their multi-functions and compactness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of a semiconductor device according to some embodiments, and FIG. 1B, FIG. 1C and FIG. 1D are respectively enlarged views of portions B, C and D of FIG. 1A.

FIG. 2 is a schematic cross-sectional view of a semiconductor device according to some embodiments.

FIG. 3A to FIG. 3F are schematic cross-sectional views of various stages in a method of forming a semiconductor device according to some embodiments.

FIG. 4A to FIG. 4E are schematic cross-sectional views of various stages in a method of forming a semiconductor device according to some embodiments.

FIG. 5A to FIG. 5D are schematic cross-sectional views of various stages in a method of forming a semiconductor device according to some embodiments.

FIG. 6 illustrates a method of forming a semiconductor device according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

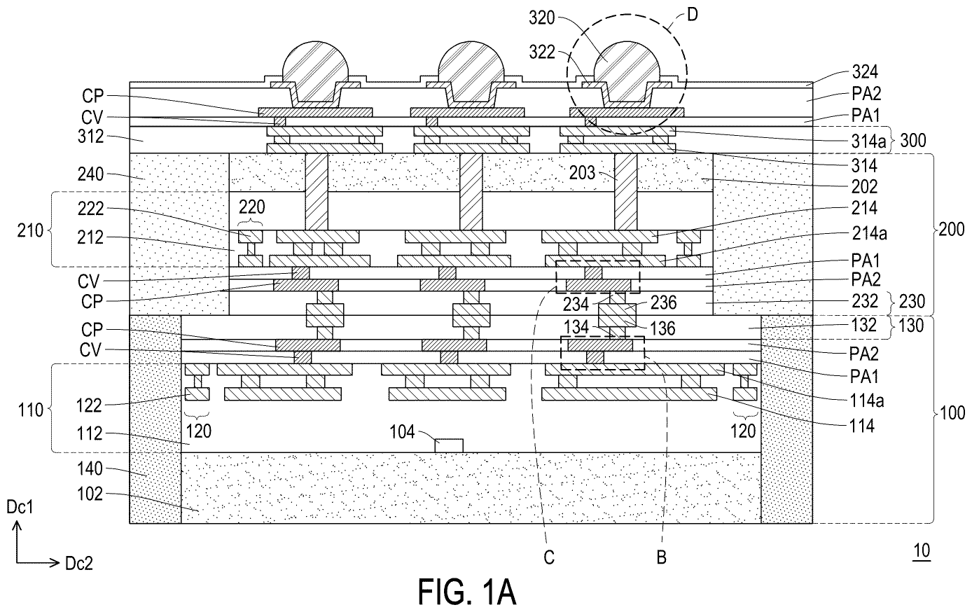

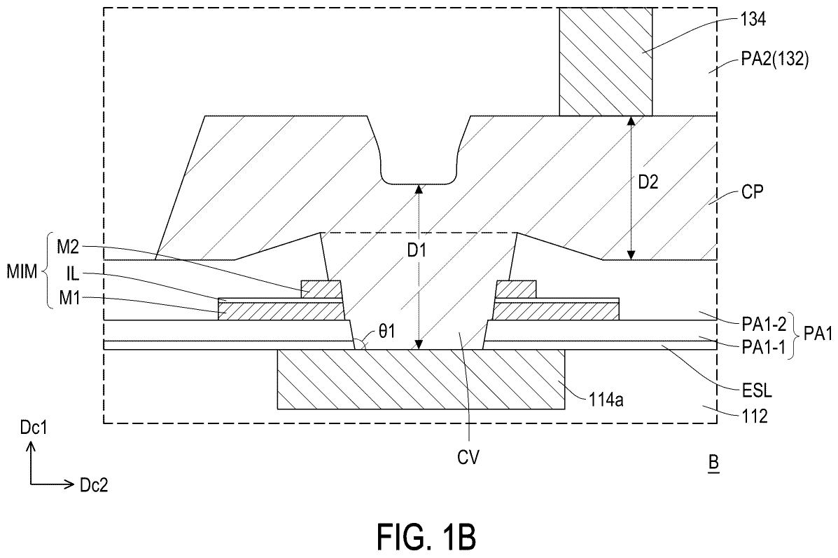

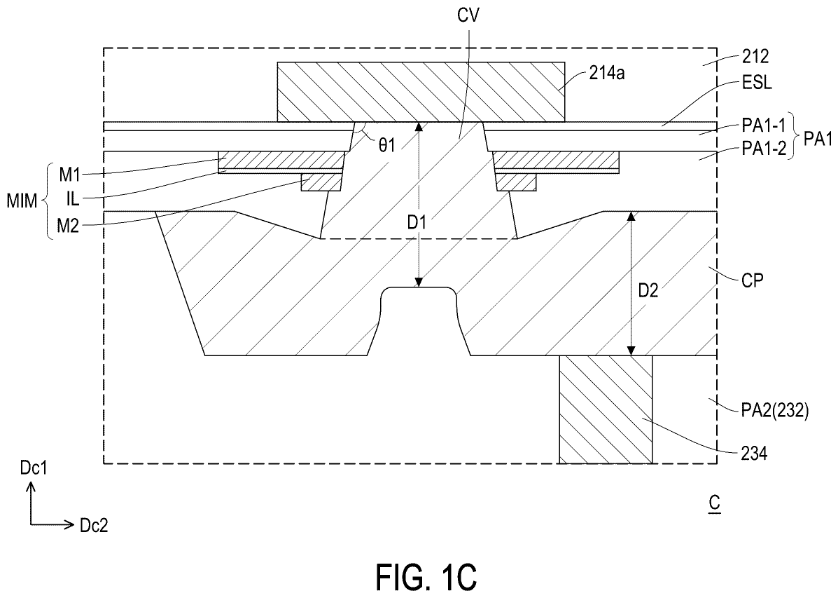

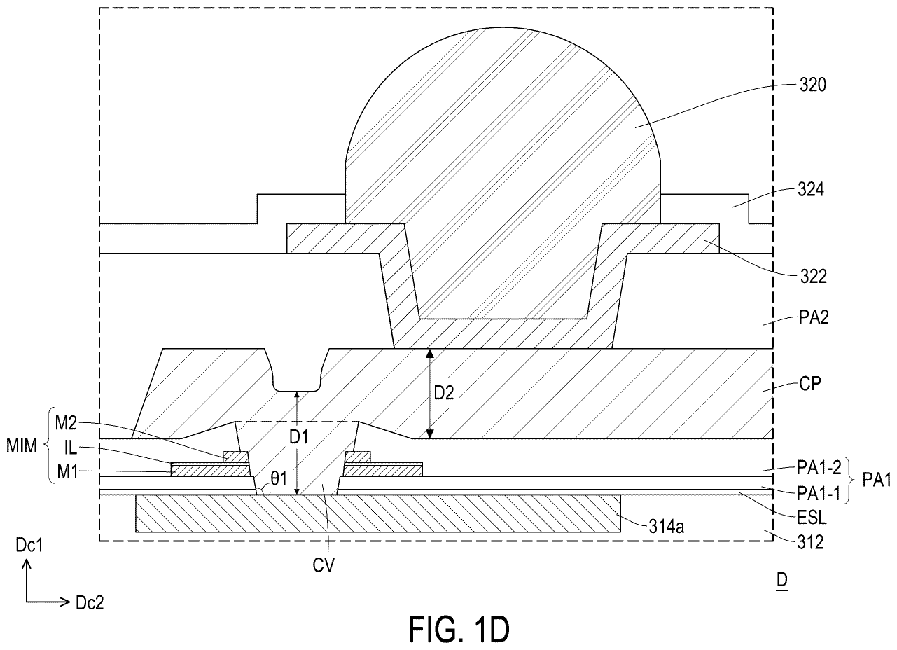

FIG. 1A is a schematic cross-sectional view of a semiconductor device according to some embodiments, and FIG. 1B, FIG. 1C and FIG. 1D are respectively enlarged views of portions B, C and D of FIG. 1A.

Referring to FIG. 1A, a semiconductor device 10 includes a plurality of integrated circuits 100, 200 bonded to each other. The integrated circuit 100, 200 may be a die such as an application-specific integrated circuit (ASIC) chip, an analog chip, a sensor chip, a wireless and radio frequency chip, a voltage regulator chip or a memory chip. The integrated circuit 200 and the integrated circuit 100 may be the same type of dies or different types of dies. In some embodiments, the integrated circuit 100 includes a semiconductor substrate 102, a device 104, an interconnect structure 110, conductive vias CV, conductive pads CP, a seal ring structure 120 and a bonding structure 130. The semiconductor substrate 102 may be a semiconductor substrate such as a substrate of silicon, doped or undoped, or an active layer of a semiconductor-on-insulator (SOI) substrate. The semiconductor substrate 102 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the semiconductor substrate 102 includes isolation structures (not shown) defining at least one active area, and a device layer is disposed on/in the active area. The device layer may include a variety of devices 104. The device 104 is, for example, a transistor, a capacitor, a resistor, a diode, a photodiode, a fuse device, or other similar device. In some embodiments, the device 104 includes a gate structure, source/drain regions, spacers, and the like.

The interconnect structure 110 is disposed over the semiconductor substrate 102. Specifically, the interconnect structure 110 is electrically connected to the device layer. In some embodiments, the interconnect structure 110 includes at least one dielectric layer 112 and a plurality of conductive features 114. The conductive features 114 are disposed in the dielectric layer 112 and electrically connected with each other, for example. Portions of the conductive feature 114, such as conductive features 114a, are exposed by the dielectric layer 112. In some embodiments, the dielectric layer 112 includes an inter-layer dielectric (ILD) layer over the semiconductor substrate 102, and at least one inter-metal dielectric (IMD) layer over the inter-layer dielectric layer. In some embodiments, the dielectric layer 112 includes silicon oxide, silicon oxynitride, silicon nitride, a low dielectric constant (low-k) material or a combination thereof. The dielectric layer 112 may be a single layer or a multiple-layer structure. In some embodiments, the conductive features 114 include plugs and lines. The plugs may include contacts formed in the inter-layer dielectric layer, and vias formed in the inter-metal dielectric layer. The contacts are formed between and in contact with a bottom metal line and the device layer. The vias are formed between and in contact with two metal lines. The conductive features 114 may include tungsten (W), copper (Cu), a copper alloy, aluminum (Al), an aluminum alloy or a combination thereof. In some embodiments, a barrier layer (not shown) may be disposed between the conductive features 114 and the dielectric layer 112 to prevent the material of the conductive features 114 from migrating to the device layer. The barrier layer includes Ta, TaN, Ti, TiN, CoW or a combination thereof, for example. In some embodiments, the interconnect structure 110 is formed by multiple single damascene processes, a dual damascene process, an electroplating process or the like.

In some embodiments, the seal ring structure 120 is formed during the formation of the interconnect structure 110. The seal ring structure 120 may include stacks of dummy conductive features 122 such as dummy conductive lines and/or dummy conductive vias. The seal ring structure 120 is disposed in a seal ring region which surrounds a circuit region, for example. The seal ring region may include a seal ring corner region at the corner of the seal ring region.

In some embodiments, as shown in FIG. 1A and FIG. 1B, the conductive pad CP is disposed on and electrically connected to the interconnect structure 110. For example, the conductive pad CP is disposed over and electrically connected to the conductive feature 114a through the conductive via CV. The conductive via CV is disposed between the interconnect structure 110 and the conductive pad CP. The conductive via CV is disposed in a passivation layer PAS1, and the conductive pad CP is disposed in a passivation layer PAS2. The conductive via CV has an angle θ1 in a range from 95 degrees to 110 degrees, and a ratio of a first distance D1 to a second distance D2 is larger than 0.8, for example. Further details of the conductive via CV and the conductive pad CP are described below.

In some embodiments, the bonding structure 130 is disposed over the conductive pad CP. The bonding conductive feature may be electrically connected to the interconnect structure 110 through the conductive pad CP. The bonding structure 130 includes at least one bonding dielectric layer 132 and a plurality of bonding conductive features. In some embodiments, the bonding dielectric layer 132 includes silicon oxide, silicon nitride, a polymer or a combination thereof. The bonding conductive features are disposed in the bonding dielectric layer 132 and electrically connected with each other. In some embodiments, the bonding conductive features include bonding vias 134 electrically connected to the conductive pad CP and bonding pads 136 electrically connected to the bonding vias 134. The bonding conductive features may include tungsten (W), copper (Cu), a copper alloy, aluminum (Al), an aluminum alloy or a combination thereof. In some embodiments, a barrier layer (not shown) is disposed between the bonding conductive features and the bonding dielectric layer 132. The barrier layer includes Ta, TaN, Ti, TiN, CoW or a combination thereof, for example. In some embodiments, the bonding structure 130 is formed by multiple single damascene processes, a dual damascene process, an electroplating process or the like.

The integrated circuit 200 is bonded to the integrated circuit 100 along a first direction Dc1. The first direction Dc1 is z direction, and a second direction Dc2 perpendicular to the first direction Dc1 is x direction, for example. For example, the integrated circuit 200 and the integrated circuit 100 are face-to-face bonded. In some embodiments, the integrated circuit 200 is similar to the integrated circuit 100. For example, the integrated circuit 200 includes a semiconductor substrate 202, a device 204, an interconnect structure 210, conductive vias CV, conductive pads CP, a seal ring structure 220 and a bonding structure 230. In some embodiments, the semiconductor substrate 202, the device 204, the interconnect structure 210, the seal ring structure 220 and the bonding structure 230 are respectively similar to the semiconductor substrate 102, the device 104, the interconnect structure 110, the seal ring structure 120 and the bonding structure 130, so the detailed description thereof is omitted herein.

In some embodiments, the interconnect structure 210 is disposed between the semiconductor substrate 202 and the bonding structure 230. The interconnect structure 210 includes at least one dielectric layer 212 and a plurality of conductive features 214. The conductive features 214 are disposed in the dielectric layer 212 and electrically connected with each other, for example. Portions of the conductive features 214, such as conductive features 214a, are exposed by the dielectric layer 212. In some embodiments, the semiconductor substrate 202 has a through via 203 therein. The through via 203 extends from the semiconductor substrate 202 to a portion of the dielectric layer 212, to electrically connect to the conductive feature 214. The seal ring structure 220 may include stacks of dummy conductive features 222 such as dummy conductive lines and/or dummy conductive vias. The seal ring structure 220 is disposed in a seal ring region which surrounds a circuit region, for example. The seal ring region may include a seal ring corner region at the corner of the seal ring region.

Similarly, the conductive pad CP is electrically connected to the interconnect structure 210. For example, as shown in FIG. 1A and FIG. 1C, the conductive pad CP is electrically connected to the conductive feature 214a through the conductive via CV. The conductive via CV is disposed between the interconnect structure 210 and the conductive pad CP. The conductive via CV is disposed in a passivation layer PAS1, and the conductive pad CP is disposed in a passivation layer PAS2 over the passivation layer PAS1. The conductive via CV has an angle θ1 in a range from 95 degrees to 110 degrees, and a ratio of a first distance D1 to a second distance D2 is larger than 0.8, for example. Further details of the conductive via CV and the conductive pad CP are described below.

In some embodiments, the bonding structure 230 includes at least one bonding dielectric layer 232 and a plurality of bonding conductive features. In some embodiments, the bonding conductive features include bonding vias 234 electrically connected to the interconnect structure 210 and bonding pads 236 electrically connected to the bonding vias 234. In some embodiments, a barrier layer (not shown) is disposed between the bonding conductive features and the bonding dielectric layer 232. The barrier layer includes Ta, TaN, Ti, TiN, CoW or a combination thereof, for example. In some embodiments, the integrated circuit 200 and the integrated circuit 100 are face-to-face bonded together by bonding the bonding dielectric layer 232 and the bonding dielectric layer 132 and bonding the bonding pads 236 and the bonding pads 136.

In some embodiments, the RDL structure 300 is disposed over the integrated circuits 100, 200. The RDL structure 300 may include at least one dielectric layer 312 and a plurality of conductive features 314. The conductive features 314 are disposed in the dielectric layer 312 and electrically connected with each other, for example. Portions of the conductive features 314, such as conductive features 314a, are exposed by the dielectric layer 312. The through via 203 may electrically connect to the conductive feature 314.

In some embodiments, as shown in FIG. 1A and FIG. 1D, a conductive pad CP is disposed on and electrically connected to the conductive feature 314a through a conductive via CV. The conductive via CV is disposed between the interconnect structure 210 and the conductive pad CP. The conductive via CV is disposed in a passivation layer PAS1, and the conductive pad CP is disposed in a passivation layer PAS2. In some embodiments, a conductive connector 320 is disposed over the conductive pad CP to electrically connect to the conductive pad CP. The conductive connector 320 may be a bump or the like. In some embodiments, a under bump metallization (UBM) layer 322 is further disposed under the conductive connector 320 for mounting conductive connector. A passivation layer 324 may be disposed on the passivation layer PAS2 to cover an edge of the UBM layer 322 and expose a center portion of the UBM layer 322, and the conductive connector 320 is formed on and in the passivation layer 324 to electrically connect to the UBM layer 322. In some embodiments, the passivation layer 324 includes silicon oxide, silicon nitride, benzocyclobutene (BCB) polymer, polyimide (PI), polybenzoxazole (PBO), a combination thereof, or the like, and is formed by a suitable process such as spin coating, CVD or the like. The conductive via CV has an angle θ1 in a range from 95 degrees to 110 degrees, and a ratio of a first distance D1 to a second distance D2 is larger than 0.8, for example. Further details of the conductive via CV and the conductive pad CP are described below.

The sizes of the integrated circuits 100, 200 may be different or the same. For example, as shown in FIG. 1A, the integrated circuit 100 is larger than the integrated circuit 200. In some embodiments, an encapsulant 140 is formed to encapsulate the integrated circuit 100, and an encapsulant 240 is formed to encapsulate the integrated circuit 200. In some embodiments, the encapsulant 140, 240 includes a molding compound, a molding underfill, a resin, a polymer material such as polybenzoxazole (PBO), polyimide and benzocyclobutene (BCB), an insulating material such as silicon oxide and silicon nitride or a combination thereof. However, the disclosure is not limited thereto. In alternative embodiments, at least one of the encapsulants 140, 240 may be omitted according to the sizes of the integrated circuits 100, 200. For example, the encapsulant 140 may be omitted when the integrated circuit 100 is a wafer-level structure. In alternative embodiments, more dies and/or dummy dies may be integrated into the semiconductor device 10.

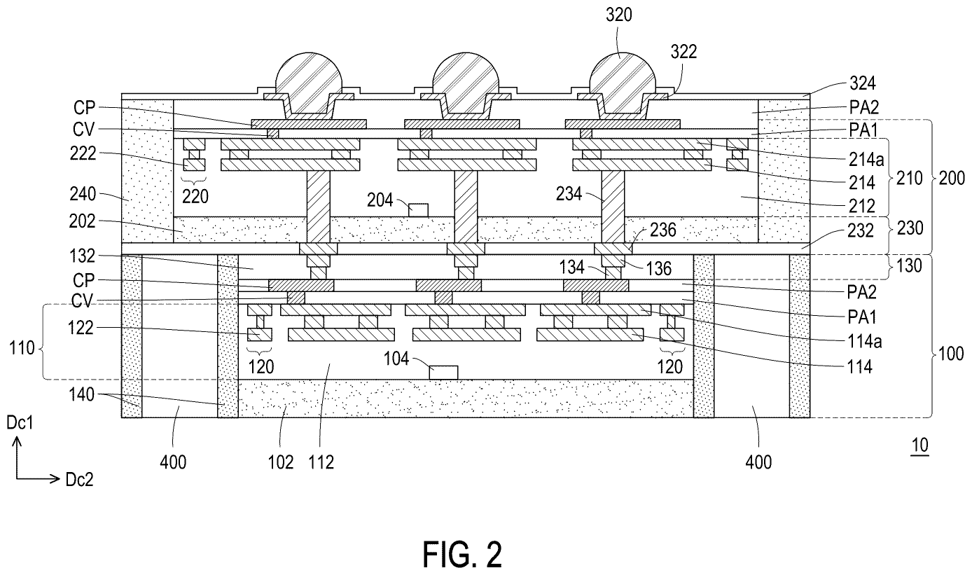

The semiconductor device 10 may have any other suitable configuration. In alternative embodiments, as shown in FIG. 2, the semiconductor device 10 is similar to the semiconductor device 10 of FIG. 1A, the main difference lies in that the integrated circuit 100 and the integrated circuit 200 are face-to-back bonded. In some embodiments, the semiconductor substrate 202 is disposed between the interconnect structure 210 and the bonding structure 230. The bonding via 234 extends through the semiconductor substrate 202 and the dielectric layer 212 to electrically connect the bonding pad 236 and the interconnect structure 210. In some embodiments, the bonding pad 236 is disposed in the bonding dielectric layer 232, and the bonding dielectric layer 232 may extend over the encapsulant 140 and the integrated circuit 100. In some embodiments, as shown in FIG. 2, the conductive pad CP is electrically connected to the interconnect structure 210 through the conductive via CV and electrically connected to the conductive connectors 320. The conductive connector 320, the UBM layer 322 and the passivation layer 324 are similar to those described with reference to FIG. 1A, so the detailed description thereof is omitted herein. In some embodiments, the integrated circuit 100 may have a size smaller than the integrated circuit 200, and a plurality of dummy dies 400 may be integrated with the integrated circuit 100 by the encapsulant 140.

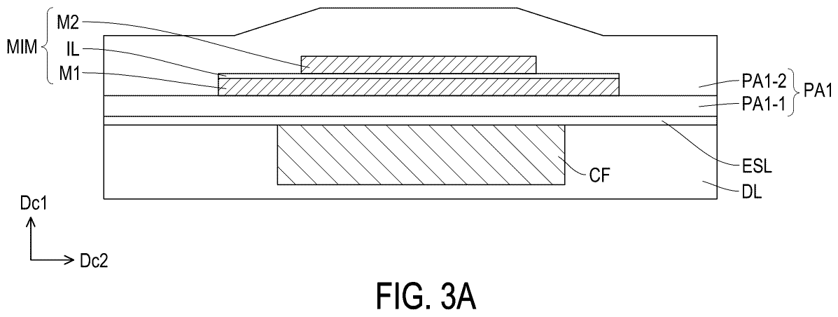

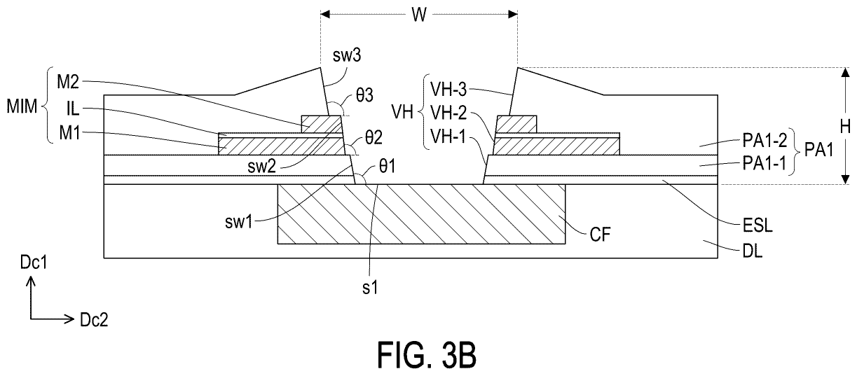

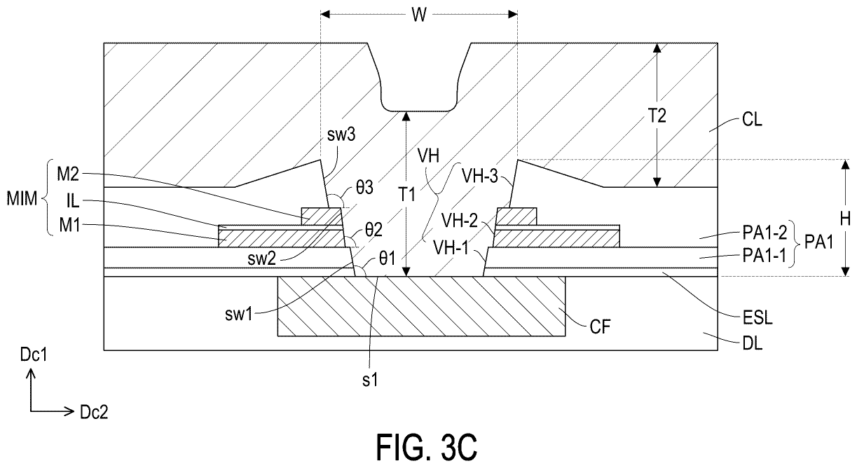

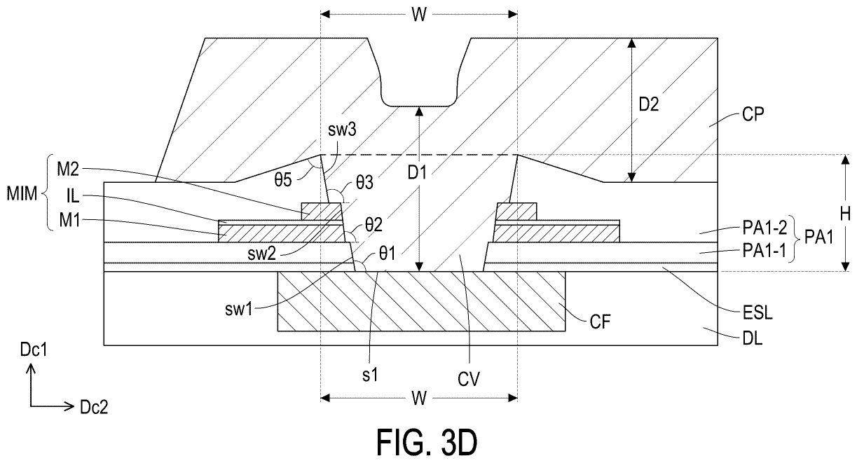

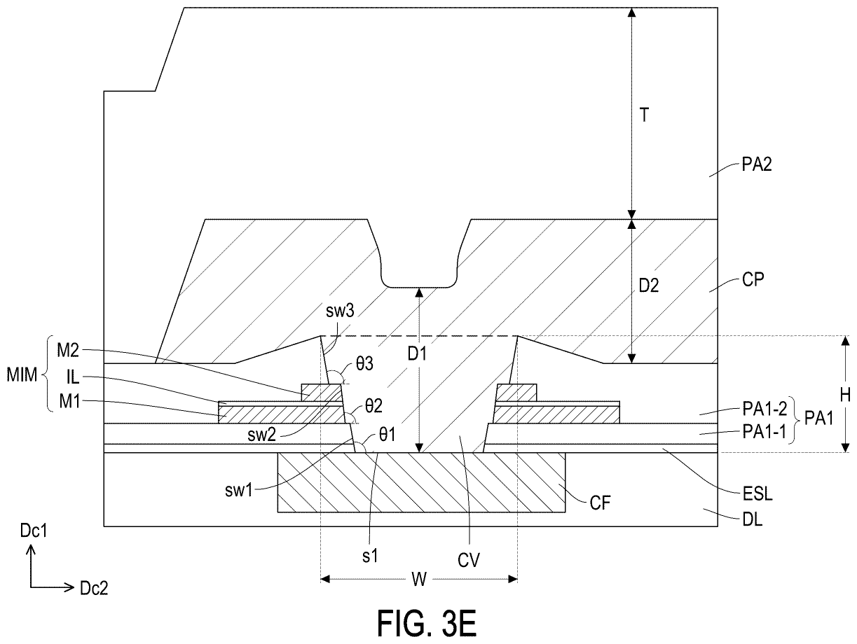

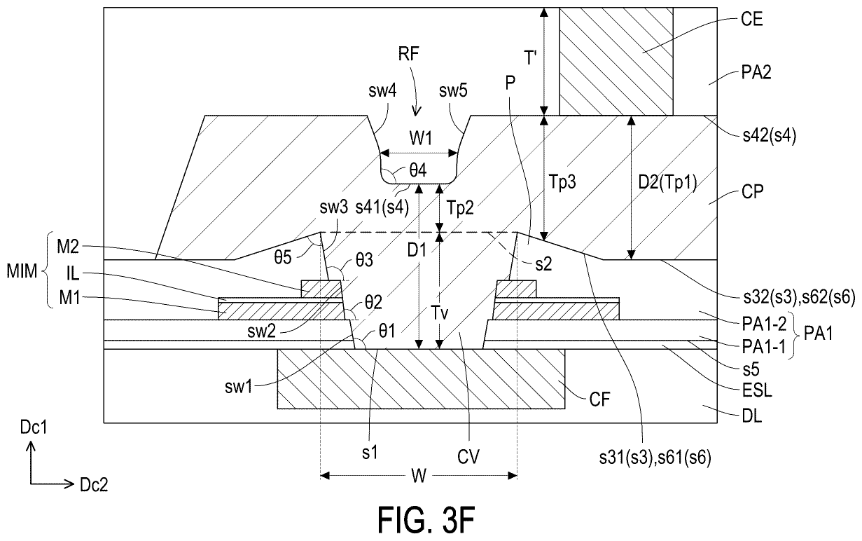

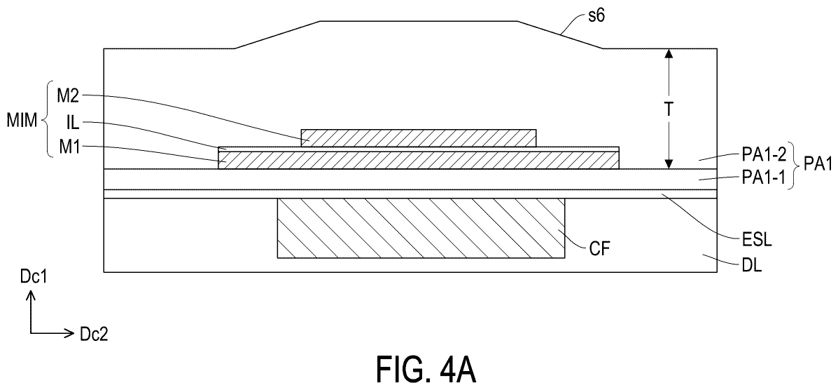

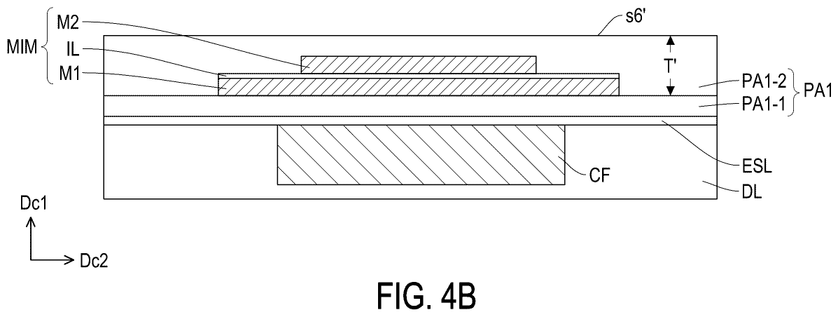

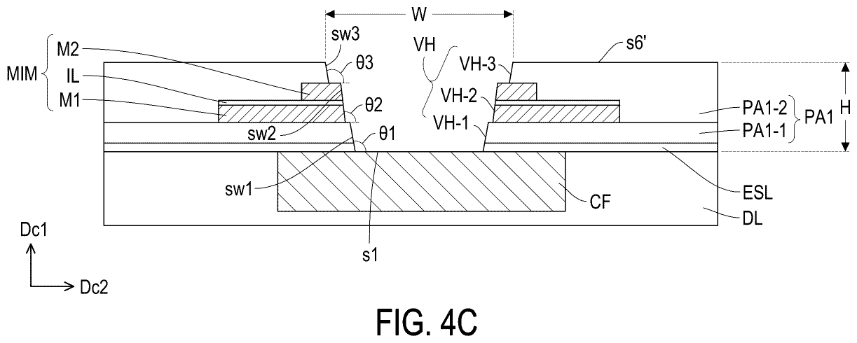

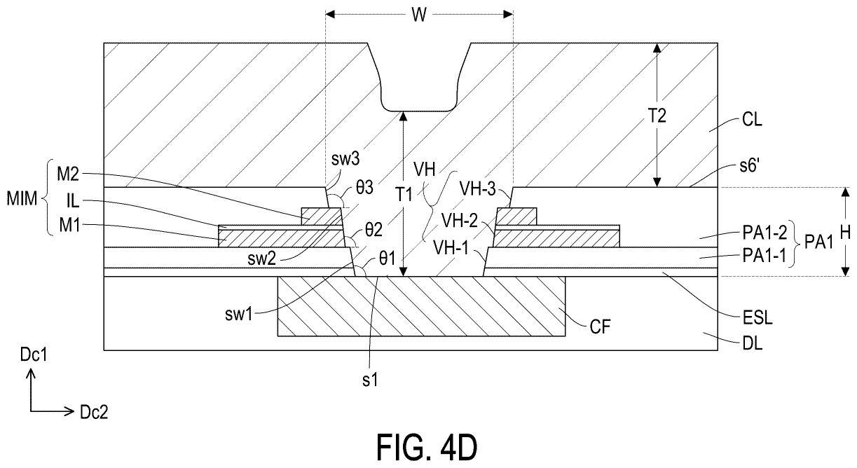

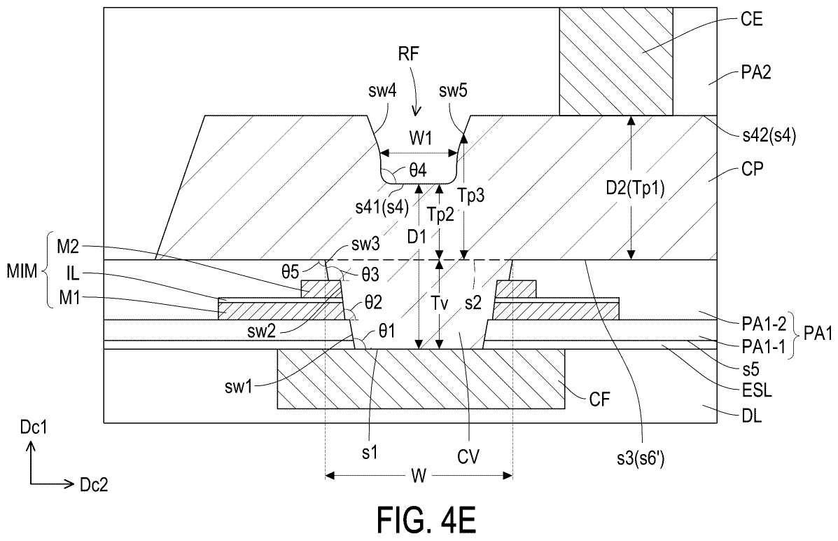

In the above embodiments, the conductive via CV and conductive pad CP may be formed by using the following method of FIG. 3A to FIG. 4F, FIG. 4A to FIG. 4E or the like and have the following configurations.

FIG. 3A to FIG. 3F are schematic cross-sectional views of various stages in a method of forming a semiconductor device according to some embodiments.

Referring to FIG. 3A, a passivation layer PA1 is formed on a conductive feature CF in a dielectric layer DL. In some embodiments, the conductive feature CF is the conductive feature 114a, 214a or 314a in FIG. 1A and FIG. 2, and the dielectric layer DL is the dielectric layer 112, 212 or 312 in FIG. 1A and FIG. 2. In some embodiments, a sub-passivation layer PA1-1 of the passivation layer PA1 is formed on the conductive feature CF. The sub-passivation layer PA1-1 is formed over the dielectric layer DL to cover the top surface of the conductive feature CF. In some embodiments, the sub-passivation layer PA1-1 includes silicon oxide, silicon nitride, benzocyclobutene (BCB) polymer, polyimide (PI), polybenzoxazole (PBO), a combination thereof, or the like, and is formed by a suitable process such as spin coating, CVD or the like. For example, the sub-passivation layer PA1-1 includes silicon oxide. The sub-passivation layer PA1-1 may be a single layer or a multilayer. An etch stop layer ESL is formed between the dielectric layer DL and the sub-passivation layer PA1-1, for example.

In some embodiments, then, a MIM structure MIM is formed on the sub-passivation layer PA1-1. The MIM structure MIM may include a metal layer M1, an insulator layer IL and a metal layer M2, and the insulator layer IL is disposed between the metal layer M1 and the metal layer M2. For example, the metal layer M1 is formed on the sub-passivation layer PA1-1, the insulator layer IL is formed on the metal layer M1, and the metal layer M2 is formed on the insulator layer IL. The thickness of the MIM structure MIM along z direction is in a range from 1K Å to 1.5K Å, for example. The metal layer M1 and the metal layer M2 may include a titanium (Ti) layer, a titanium nitride (TiN) layer, a tatanium (Ta) layer, a tatanium nitride (TaN) layer, or combinations thereof. The insulator layer IL may include a nitride layer, a silicon nitride layer, or other dielectric layers of high dielectric constant.

After that, a sub-passivation layer PA1-2 of the passivation layer PA1 is formed on the sub-passivation layer PA1-1 to cover the MIM structure MIM, for example. In some embodiments, the sub-passivation layer PA1-1 includes silicon oxide, silicon nitride, benzocyclobutene (BCB) polymer, polyimide (PI), polybenzoxazole (PBO), a combination thereof, or the like, and is formed by a suitable process such as spin coating, CVD or the like. For example, the sub-passivation layer PA1-2 includes silicon oxide. The material of the sub-passivation layer PA1-2 may be the same as or different from the sub-passivation layer PA1-1. The sub-passivation layer PA1-2 may be a single layer or a multilayer. In some embodiments, the sub-passivation layer PA1-1 and the sub-passivation layer PA1-2 may be collectively referred to as passivation layer or first passivation layer PA1. A total thickness of the passivation layer PA1 (e.g., a total thickness of the sub-passivation layer PA1-1 and the sub-passivation layer PA1-2) is in a range from 1K Å to 2K Å, for example. The thickness of the sub-passivation layer PA1-1 may be smaller than the thickness of the sub-passivation layer PA1-2.

Referring to FIG. 3B, a via hole VH is formed in the passivation layer PA1 to expose the conductive feature CF. In some embodiments, the via hole VH is formed in the sub-passivation layer PA1-1, the MIM structure MIM and the sub-passivation layer PA1-2. For example, the sub-passivation layer PA1-2 is patterned with a lithography process and an etch process to form a via hole VH-3, the MIM structure MIM is patterned with a lithography process and an etch process to form a via hole VH-2, and the sub-passivation layer PA1-1 and the etch stop layer ESL are patterned with a lithography process and an etch process to form a via hole VH-1. In some embodiments, the via holes RV-1, RV-2 and RV-3 may be collectively referred to as via hole or redistribution via hole VH.

In some embodiments, a height H of the via hole VH is in a range from 0.8 μm to 1.5 μm and a width W of the via hole VH is in a range from 1.8 μm to 3.5 μm. The width W of the via hole VH increases as the via hole VH becomes away from the conductive feature CF. For example, a width of the via hole VH-3 is larger than a width of the via hole VH-2, and the width of the via hole VH-2 is larger than a width of the via hole VH-1. The sidewall of the via hole VH-1 may be inside the sidewall of the via hole VH-2, and the sidewall of the via hole VH-2 may be inside the sidewall of the via hole VH-3. However, the disclosure is not limited thereto.

In some embodiments, an angle θ1 is formed between the sidewall and the bottom surface s1 of the via hole VH (e.g., via hole VH-1). The angle θ1 may be in a range from 95 degrees to 110 degrees. For example, the angle θ1 is larger than 95 degrees and smaller than 110 degrees. Depending on the materials of the sub-passivation layers PA1-1 and PA1-2 and the MIM structure MIM, an angle θ2 formed between the sidewall of the via hole VH-2 and the bottom surface s1 and an angle θ3 formed between the sidewall of the via hole VH-3 and the bottom surface s1 may be different from or substantially equal to the angle θ1. In some embodiments, the angle θ2 may be different from the angle θ1 since the materials of the MIM structure MIM are different from the material of the sub-passivation layer PA1-1. For example, the angle θ2 is larger than or smaller than the angle θ1. The angle θ3 may be substantially equal to the angle θ1 if the materials of the sub-passivation layer PA1-1 and the sub-passivation layer PA1-2 have similar or substantially the same material (i.e., similar or substantially the same etch selectivity with respect to the etchant). Accordingly, the inclination of the sidewall of the via hole VH-2 may be different from the sidewall of the via hole VH-1, and the inclination of the sidewall of the via hole VH-3 may be similar to the inclination of the sidewall of the via hole VH-1. However, the disclosure is not limited thereto.

In some embodiments, the angle θ1 may be controlled in the range of 95 degrees to 110 degrees by adjusting the ratio of the carbon to the fluoride in the etch gas. The ratio of the carbon to the fluoride in the etch gas may be in a range from 1 to 5. For example, in the etch process, the gas flow rate of trifluoromethane (CHF₃) is in a range from 100 sccm to 400 sccm, the gas flow rate of tetrafluoromethane (CF₄) is in a range from 100 sccm to 500 sccm, the gas flow rate of octafluorocyclobutane (C₄F₈) is in a range from 0 sccm to 60 sccm, the gas flow rate of sulfur hexafluoride (SF₆) is in a range from 0 sccm to 100 sccm and/or the gas flow rate of nitrogen (N₂) is in a range from 0 sccm to 100 sccm.

Referring to FIG. 3C, a conductive layer CL is formed over the passivation layer PA1 to fill the via hole VH. The conductive layer CL may be formed by a deposition process such as PVD process. The thickness of the conductive layer CL is in a range from 26K Å to 30K Å, for example. In some embodiments, the conductive layer CL has a first thickness (e.g., minimum thickness) T1 on the conductive feature CF and a second thickness (e.g., maximum thickness) T2 on the passivation layer PA1 along the first direction Dc1 (e.g., z direction), and a ratio of the first thickness T1 to the second thickness T2 is larger than 0.8. The ratio of the first thickness T1 to the second thickness T2 may be larger than 0.8 and smaller than 1. In some embodiments, the above thickness ratio may be achieved by controlling the power, the temperature and the like for the deposition process. For example, a direct current (DC) power may be biased with a frequency in a range from 10K W to 30K W and an alternating current power may be biased with a frequency in a range from 100 W to 1000 W. The temperature of the deposition process may be in a range from 300° C. to 400° C. The conductive layer CL is aluminum copper layer, for example.

Referring to FIG. 3D, the conductive layer CL is patterned, to form a conductive via CV in the via hole VH and a conductive pad CP on the conductive via CV and the passivation layer PA1. The conductive layer CL is patterned by using a lithography process and an etch process, for example. In some embodiments, the conductive via CV has a bottom surface s1 and the sidewall sw1, and an angle θ1 formed between the bottom surface s1 and the sidewall sw1 is substantially equal to the angle θ1 of the via hole VH, that is, larger than 95 degrees and smaller than 110 degrees. In some embodiments, the conductive pad CP and the conductive via CV are integrally formed and thus have same material. The conductive via CV may be also referred to as redistribution via, and the conductive pad CP may be also referred to as aluminum-copper pad, aluminum pad or aluminum line. Further details of the conductive via CV and the conductive pad CP are described below with reference to FIG. 3F.

Referring to FIG. 3E, a passivation layer PA2 is formed on the conductive pad CP and the passivation layer PA1. For example, the passivation layer PA2 is formed to cover the conductive pad CP and the passivation layer PA1. In some embodiments, the passivation layer PA2 includes silicon oxide, silicon nitride, benzocyclobutene (BCB) polymer, polyimide (PI), polybenzoxazole (PBO), a combination thereof, or the like, and is formed by a suitable process such as spin coating, CVD or the like. For example, the passivation layer PA2 includes silicon oxide. The material of the passivation layer PA2 may be the same as or different from the sub-passivation layer PA1-1 and the sub-passivation layer PA1-2. In some embodiments, the sub-passivation layer PA1-1 and the sub-passivation layer PA1-2 of the passivation layer PA1 and the passivation layer PA2 include silicon oxide. The passivation layer PA2 may be a single layer or a multilayer. The thickness T of the passivation layer PA2 on the conductive pad CP may be in a range from 40K Å to 60K Å. The passivation layer PA2 may be conformally formed on the conductive pad CP and the passivation layer PA1. Due to the conductive pad CP, the passivation layer PA2 may have a protruded surface.

In some embodiments, as shown in FIG. 3F, a planarization process may be further performed on the passivation layer PA2 to obtain a substantially flat top surface. The planarization process is a CMP process, for example. After the planarization process, the thickness T′ of the passivation layer PA2 over the conductive pad CP may be in a range from 6K Å to 12K Å. Then, as shown in FIG. 3F, a conductive element CE is formed in the passivation layer PA2 to electrically connect to the conductive pad CP. The conductive element CE may be the bonding via 134, 234 and the conductive connector 320 of FIG. 1A and FIG. 2 or the like.

The conductive via CV may be in direct contact with inner sidewalls of the sub-passivation layer PA1-1, the sub-passivation layer PA1-2 and the metal layer M1, the insulator layer IL and the metal layer M2 of the MIM structure MIM. In some embodiments, the conductive via CV may have the sidewall sw1 interfacing with the sub-passivation layer PA1-1, a sidewall sw2 interfacing with the MIM structure MIM and a sidewall sw3 interfacing with the sub-passivation layer PA1-2. The angle θ1 formed between the sidewall sw1 and the bottom surface s1 may be in a range from 95 degrees to 110 degrees. As mentioned above, depending on the materials of the sub-passivation layers PA1-1 and PA1-2 and the MIM structure MIM, an angle θ2 formed between the sidewall sw2 and the bottom surface s1 and an angle θ3 formed between the sidewall sw3 and the bottom surface s1 may be different from or substantially equal to the angle θ1. For example, as shown in FIG. 3F, the angle θ2 is different from the angle θ1, and the angle θ3 is substantially the same as the angle θ1. Accordingly, the inclination of the sidewall sw2 is different from the inclination of the sidewall sw1, and the inclination of the sidewall sw3 is similar to or substantially the same as the inclination of the sidewall sw1. However, the disclosure is not limited thereto. In alternative embodiments, the angle θ3 (e.g., 90 degrees) is different from the angle θ1, and the inclination of the sidewall sw3 is different from the inclination of the sidewall sw1.

The conductive via CV is disposed in the passivation layer PA1, and the conductive pad CP continuously extends on the conductive via CV and the passivation layer PA1, for example. The conductive via CV has a surface s1 (e.g., bottom surface) facing the conductive feature CF and a surface s2 (e.g., top surface) opposite to the surface s1. The conductive pad CP has a surface s3 (e.g., bottom surface) facing the conductive via CV and the passivation layer PA1 and a surface s4 (e.g., top surface) opposite to the surface s3. The minimum distance between the surface s1 and the surface s4 (e.g., surface s41) along the first direction Dc1 (e.g., z direction) is a first distance D1, the maximum distance between the surface s3 and the surface s4 (e.g., surface s42) along the first direction Dc1 (e.g., z direction) is a second distance D2, and a ratio of the first distance D1 to the second distance D2 is larger than 0.8. The ratio of the first distance D1 to the second distance D2 may be larger than 0.8 and smaller than 1. In some embodiments, due to the via hole VH, the surface s4 of the conductive pad CP includes a recessed portion/surface s41 and a substantially planar portion/surface s42. The first distance D1 is formed between the surface s1 and the recessed surface s41 of the surface s4, and the second distance D2 is formed between the surface s3 and the substantially planar surface s42 of the surface s4. In some embodiments, a height H of the conductive via CV is in a range from 0.8 μm to 1.5 μm and a width W of the conductive via CV is in a range from 1.8 μm to 3.5 μm. The width W of the conductive via CV increases as the conductive via CV becomes away from the conductive feature CF.

The substantially planar surface s42 of the conductive pad CP provides a substantially planar surface for the formation of the conductive elements CE such as the bonding via 134, 234 and the connector 320 of FIG. 1A and FIG. 2. For example, as shown in FIG. 1B to FIG. 1D, the bonding via 134, 234 and the connector 320 are respectively disposed on the substantially planar surface s42 of the of the conductive pad CP. The recessed surface s41 may be disposed at a height between the substantially planar surface s42 and a surface s6 (e.g., top surface) of the first passivation layer PA1. That is, the recessed surface s41 may be higher than the surface s6 of the first passivation layer PA1 and lower than the substantially planar surface s42. In such embodiments, the conductive pad CP has a recessed feature RF, and a portion of the passivation layer PA2 is disposed in the recessed feature RF. The recessed feature RF has a surface s41 and opposite sidewalls sw4, sw5 connecting to the surface s41. In some embodiments, a distance between the sidewalls sw4, sw5 (i.e., width W1 of the recessed feature RF along the second direction Dc2 (e.g., x direction)) continuously increases as the recessed feature RF becomes away from the conductive feature CF along the first direction Dc1 (e.g., z direction). An angle θ4 formed between the surface s41 and the sidewall sw4, sw5 is larger than the angle θ1, for example. The recessed feature RF is inverted trapezoid shaped, for example. By contrast, in an embodiment in which the angle θ1 is outside the range from 95 degrees to 110 degrees and/or the ratio of the first distance D1 to the second distance D2 is smaller than 0.8, the recessed feature RF of the conductive pad CP may be generally hourglass shaped, which is difficult to the gap-filling of the passivation layer PA2 and thus may result in seam in the passivation layer PA2 and cause crack in the passivation layer PA2 in the subsequent process. In other words, in some embodiments, the recessed feature RF of the conductive pad CP provides a smooth profile, and thus the passivation layer PA2 may be filled in the recessed feature RF without seam defects. Accordingly, crack subsequently formed in the passivation layer PA2 may be prevented. For example, the occurrence of seam and/or crack in the passivation layer PA2 in the seal ring region (e.g., seal ring corner region) may be prevented.

In some embodiments, the MIM structure MIM is embedded in the passivation layer PA, for example, the MIM structure MIM is sandwiched between the sub-passivation layer PA1-1 and the sub-passivation layer PA1-2. The MIM structure MIM is also referred to as a MIM capacitor. In some embodiments, the first metal layer M1 is electrically connected to the conductive via CV, the second metal layer M1 is electrically connected to the conductive via CV, and the insulator layer IL is disposed between the first metal layer M1 and the second metal layer M1. The passivation layer PA1 has a surface (e.g., bottom surface) s5 facing the conductive feature CP and a surface s6 opposite to the surface (e.g., top surface) s6 opposite to the surface s5. Due to the MIM structure MIM, the passivation layer PA1 (i.e., the sub-passivation layer PA1-2) formed thereover may have an uneven surface s6. For example, the surface s6 has an inclined portion/surface s61 on the MIM structure MIM and a substantially planar portion/surface s62 aside the inclined surface s61, and an angle θ5 is formed between the sidewall sw3 and the inclined surface s61. The angle θ5 may be in a range from 70 degrees to 90 degrees. Thus, as shown in FIG. 3F, the passivation layer PA1 has a protrusion P protruded into the conductive pad CP. In such embodiments, the surface s3 of the conductive pad CP is also uneven and has an inclined portion/surface s31 corresponding to the inclined surface s61 and a substantially planar portion/surface s32 corresponding to the substantially planar surface s62. Accordingly, the conductive pad CP may have a maximum thickness Tp1 on the substantially planar surface s62 of the passivation layer PA1, a minimum thickness Tp2 on the conductive via CV and a variable thickness Tp3 between the maximum thickness Tp1 and the minimum thickness Tp2. The first distance D1 is equal to a total of a thickness Tv of the conductive via CV and the minimum thickness Tp2 of the conductive pad CP, and the second distance D2 is equal to the maximum thickness Tp1 of the conductive pad CP, for example. The thickness Tv of the conductive via CV is substantially constant, for example.

FIG. 4A to FIG. 4E are schematic cross-sectional views of various stages in a method of forming a semiconductor device according to some embodiments. The method of FIG. 4A to FIG. 4E may be similar to the method of FIG. 3A to FIG. 3F, and the difference lies in that a planarization process is further performed on the passivation layer.

Referring to FIG. 4A, in some embodiments, after the sub-passivation layer PA1-1 of the passivation layer PA1 and the MIM structure MIM are sequentially formed over the conductive feature CF, a sub-passivation layer PA1-2 of the passivation layer PA1 is formed on the sub-passivation layer PA1-1 to cover the MIM structure MIM. The material and the forming method of the sub-passivation layer PA1-1, the MIM structure MIM and the sub-passivation layer PA1-2 may be similar to those described with reference to FIG. 3A, so the detailed description thereof is omitted herein. In some embodiments, for the sequential planarization process, a total thickness T of the passivation layer PA1 (e.g., a total thickness of the sub-passivation layer PA1-1 and the sub-passivation layer PA1-2) is in a range from 3K Å to 4K Å. The thickness of the sub-passivation layer PA1-1 may be smaller than the thickness of the sub-passivation layer PA1-2. In some embodiments, as shown in FIG. 4A, the sub-passivation layer PA1-2 may be conformally formed on the MIM structure MIM and thus may have an uneven surface (e.g., top surface) s6.

Referring to FIG. 4B, a planarization process is performed on the surface s6 of the passivation layer PA1. In some embodiments, the planarization process is performed on the surface s6 of the sub-passivation layer PA1-2. The planarization process is a CMP process, for example. After the planarization process, a total thickness T′ of the passivation layer PA1 (e.g., a total thickness of the sub-passivation layer PA1-1 and the sub-passivation layer PA1-2) is in a range from 1K Å to 2K Å. As shown in FIG. 4B, the passivation layer PA1 (e.g., passivation layer PA1-2) may have a substantially flat surface s6′ after the planarization process.

Referring to FIG. 4C, a via hole VH is formed in the passivation layer PA1 to expose the conductive feature CF. The forming method of the via hole VH may be similar to that described with reference to FIG. 3B, so the detailed description thereof is omitted herein. In some embodiments, compared to FIG. 3B, as shown in FIG. 4C, the surface s6′ of the passivation layer PA1 (e.g., passivation layer PA1-2) surrounding/connecting the formed via hole VH is substantially flat. In some embodiments, the via hole VH may be maintained in a desired height H such as in a range from 0.8 μm to 1.5 μm by controlling the initial thickness T of the passivation layer PA1 and the removal thickness of the passivation layer PA1 during the planarization process. An angle θ1 formed between the sidewall sw1 and the bottom surface s1 of the via hole VH (e.g., via hole VH-1) is in a range from 95 degrees to 110 degrees, for example. An angle θ2 formed between the sidewall sw2 of the via hole VH (e.g., via hole VH-2) and the bottom surface s1 and an angle θ3 formed between the sidewall sw3 of the via hole VH (e.g., via hole VH-3) and the bottom surface s1 may be similar to that described with reference to FIG. 3B, so the detailed description thereof is omitted herein.

Referring to FIG. 4D, a conductive layer CL is formed over the passivation layer PA1 to fill the via hole VH. The forming method of the conductive layer CL may be similar to that described with reference to FIG. 3C, so the detailed description thereof is omitted herein. In some embodiments, since the passivation layer PA1 (e.g., passivation layer PA1-2) has the substantially flat surface s6′ aside the via hole VH without protrusion, the conductive layer CL may be filled into the via hole H more easily. In some embodiments, the conductive layer CL has a first thickness (e.g., minimum thickness) T1 on the conductive feature CF and a second thickness (e.g., maximum thickness) T2 on the passivation layer PA1 along the first direction Dc1 (e.g., z direction), and a ratio of the first thickness T1 to the second thickness T2 is larger than 0.8. The ratio of the first thickness T1 to the second thickness T2 may be larger than 0.8 and smaller than 1.

Referring to FIG. 4E, the conductive layer CL is patterned to form a conductive via CV in the via hole VH and a conductive pad CP on the conductive via CV. Then, a passivation layer PA2 is formed on the conductive pad CP and the passivation layer PA1. The forming method of the conductive via CV, the conductive pad CP and the passivation layer PA2 may be similar to those described with reference to FIG. 3D to FIG. 3F, so the detailed description thereof is omitted herein. The main difference lies in that the passivation layer PA1 (e.g., passivation layer PA1-2) may have the substantially flat surface s6′.

In some embodiments, the angle θ1 formed between the sidewall sw1 and the bottom surface s1 of the conductive via CV is in a range from 95 degrees to 110 degrees. The minimum distance between the surface s1 and the surface s4 along the first direction Dc1 (e.g., z direction) is a first distance D1, the maximum distance between the surface s3 and the surface s4 along the first direction Dc1 (e.g., z direction) is a second distance D2, and a ratio of the first distance D1 to the second distance D2 is larger than 0.8. The ratio of the first distance D1 to the second distance D2 may be larger than 0.8 and smaller than 1.

In some embodiments, as shown in FIG. 4E, the passivation layer PA1 having the MIM structure MIM therein may have the substantially flat surface (e.g., top surface) s6′. For example, an angle θ5 is formed between the sidewall sw3 and the surface s6′ is larger than 90 degrees. In such embodiments, the surface s6′ of the passivation layer PA1 interfacing with the conductive pad CP may be substantially entirely flat, and the surface s3 of the conductive pad CP is also substantially entirely flat. Accordingly, the conductive pad CP may have a maximum thickness (also constant thickness) Tp1 on the surface s6′ of the passivation layer PA1, a minimum thickness Tp2 on the conductive via CV, and a variable thickness Tp3 between the maximum thickness Tp1 and the minimum thickness Tp2. The first distance D1 is equal to a total of a thickness Tv of the conductive via CV and the minimum thickness Tp2 of the conductive pad CP, and the second distance D2 is equal to the maximum thickness Tp1 of the conductive pad CP, for example. The thickness Tv of the conductive via CV is substantially constant, for example.

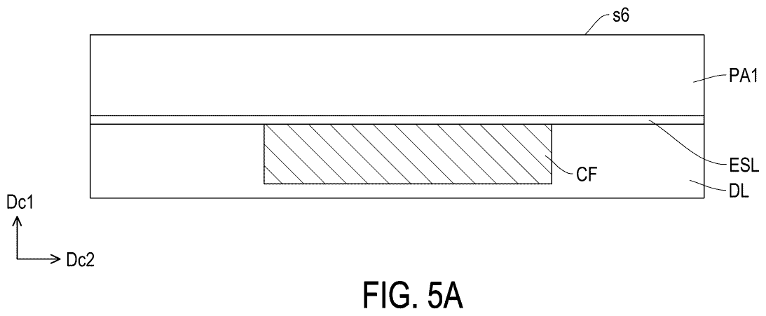

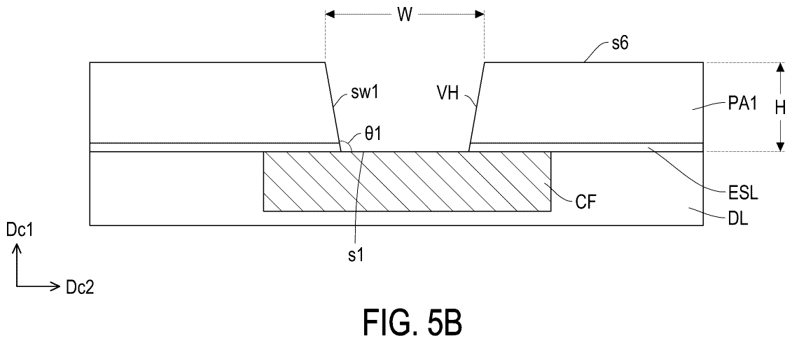

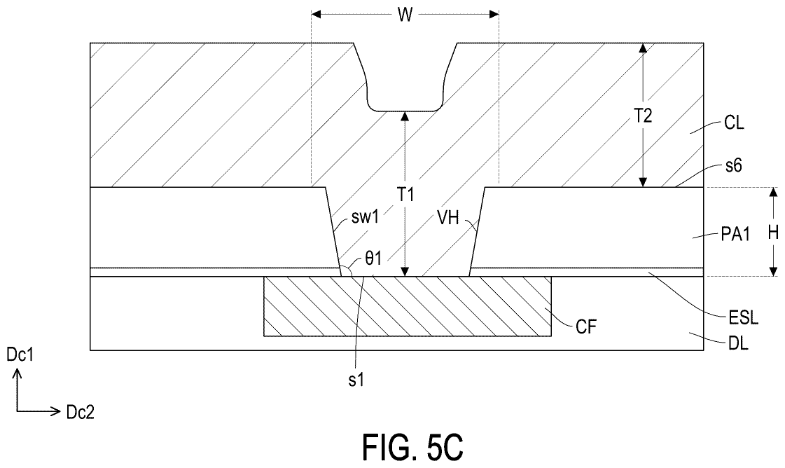

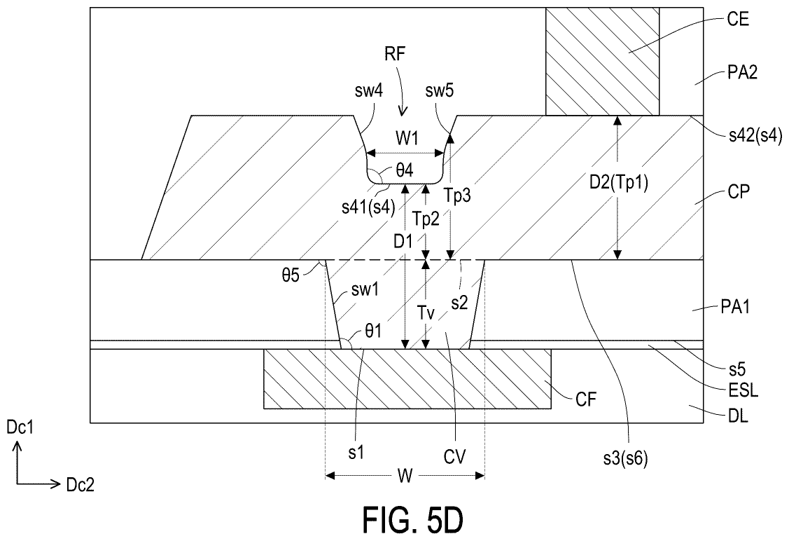

FIG. 5A to FIG. 5D are schematic cross-sectional views of various stages in a method of forming a semiconductor device according to some embodiments. The method of FIG. 5A to FIG. 5E may be similar to the method of FIG. 3A to FIG. 3F, and the difference lies in that the MIM structure MIM is omitted.

Referring to FIG. 5A, in some embodiments, a passivation layer PA1 is formed on a conductive feature CF in a dielectric layer DL. In some embodiments, the conductive feature CF is the conductive feature 114a, 214a or 314a in FIG. 1A and FIG. 2, and the dielectric layer DL is the dielectric layer 112, 212 or 312 in FIG. 1A and FIG. 2. The passivation layer PA1 is formed over the dielectric layer DL to cover the top surface of the conductive feature CF. In some embodiments, the passivation layer PA1 includes silicon oxide, silicon nitride, benzocyclobutene (BCB) polymer, polyimide (PI), polybenzoxazole (PBO), a combination thereof, or the like, and is formed by a suitable process such as spin coating, CVD or the like. For example, the passivation layer PA1 includes silicon oxide. The passivation layer PA1 may be a single layer or a multilayer. A thickness of the passivation layer PA1 is in a range from 1K Å to 2K Å, for example. The passivation layer PA1 may have a substantially flat surface s6. An etch stop layer ESL may be formed between the dielectric layer DL and the passivation layer PA1.

Referring to FIG. 5B, a via hole VH is formed in the passivation layer PA1 to expose the conductive feature CF. In some embodiments, the via hole VH is formed by patterning the passivation layer PA1 with a lithography process and an etch process. The sub-passivation layer PA1 may be a single layer or a multilayer. In some embodiments, the via hole VH may have an inclined sidewall sw1, an angle θ1 formed between the sidewall sw1 and the bottom surface s1 of the via hole VH is in a range from 95 degrees to 110 degrees. The inclined sidewall sw1 is continuously extended between opposite surfaces of the passivation layer PA1 without a turning point, for example. However, the disclosure is not limited thereto.

Referring to FIG. 5C, a conductive layer CL is formed over the passivation layer PA1 to fill the via hole VH. The forming method of the conductive layer CL may be similar to that described with reference to FIG. 3C, so the detailed description thereof is omitted herein. In some embodiments, since the passivation layer PA1 has the substantially flat surface s6 aside the via hole VH without protrusion, the conductive layer CL may be filled into the via hole VH more easily. In some embodiments, the conductive layer CL has a first thickness (e.g., minimum thickness) T1 on the conductive feature CF and a second thickness (e.g., maximum thickness) T2 on the passivation layer PA1 along the first direction Dc1 (e.g., z direction), and a ratio of the first thickness T1 to the second thickness T2 is larger than 0.8. The ratio of the first thickness T1 to the second thickness T2 may be larger than 0.8 and smaller than 1.

Referring to FIG. 5D, the conductive layer CL is patterned to form a conductive via CV in the via hole VH and a conductive pad CP on the conductive via CV. Then, a passivation layer PA2 is formed on the conductive pad CP and the passivation layer PA1. The forming method of the conductive via CV, the conductive pad CP and the passivation layer PA2 may be similar to those described with reference to FIG. 3D to FIG. 3F, so the detailed description thereof is omitted herein. The main difference lies in that the passivation layer PA1 may have the substantially flat surface s6 and the MIM structure MIM is omitted.

In some embodiments, the angle θ1 formed between the sidewall sw1 and the bottom surface s1 of the conductive via CV is in a range from 95 degrees to 110 degrees. The minimum distance between the surface s1 and the surface s4 along the first direction Dc1 (e.g., z direction) is a first distance D1, the maximum distance between the surface s3 and the surface s4 along the first direction Dc1 (e.g., z direction) is a second distance D2, and a ratio of the first distance D1 to the second distance D2 is larger than 0.8. The ratio of the first distance D1 to the second distance D2 may be larger than 0.8 and smaller than 1.

In some embodiments, as shown in FIG. 5D, the passivation layer PA1 without MIM structure therein may have the substantially flat surface (e.g., top surface) s6. For example, an angle θ5 is formed between the sidewall sw3 and the surface s6 is larger than 90 degrees. In such embodiments, the surface s6 of the passivation layer PA1 interfacing with the conductive pad CP may be substantially entirely flat, and the surface s3 of the conductive pad CP is also substantially entirely flat. Accordingly, the conductive pad CP may have a maximum thickness (also constant thickness) Tp1 on the surface s6 of the passivation layer PA1, a minimum thickness Tp2 on the conductive via CV, and a variable thickness Tp3 between the maximum thickness Tp1 and the minimum thickness Tp2. The first distance D1 is equal to a total of a thickness Tv of the conductive via CV and the minimum thickness Tp2 of the conductive pad CP, and the second distance D2 is equal to the maximum thickness Tp1 of the conductive pad CP, for example. The thickness Tv of the conductive via CV is substantially constant, for example.

In the above embodiments, the profile of the conductive via is improved by controlling the angle between 95 degrees to 110 degrees, the ratio of the first distance to the second distance larger than 0.8 and/or removal of the protrusion in the passivation layer. Thus, the passivation layer over the conductive pad may be formed in a smooth profile, and the occurrence of seam and/or crack in the passivation layer may be prevented. Accordingly, the semiconductor device including the conductive via and the conductive pad thereon may have an improved reliability.

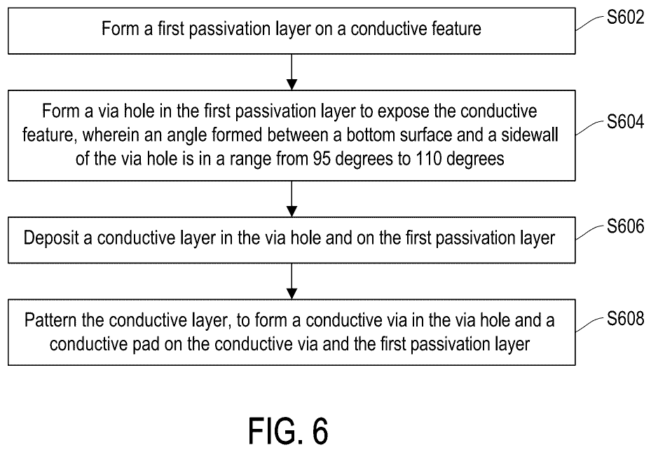

FIG. 6 illustrates a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S602, a first passivation layer is formed on a conductive feature. FIG. 3A, FIG. 4A and FIG. 4B and FIG. 5A illustrate varying views corresponding to some embodiments of act S602.

At act S604, a via hole is formed in the first passivation layer to expose the conductive feature, wherein an angle formed between a bottom surface and a sidewall of the via hole is in a range from 95 degrees to 110 degrees. FIG. 3B, FIG. 4C and FIG. 5B illustrate varying views corresponding to some embodiments of act S604.

At act S606, a conductive layer is deposited in the via hole and on the first passivation layer. FIG. 3C, FIG. 4D and FIG. 5C illustrate views corresponding to some embodiments of act S606.

At act S6608, the conductive layer is patterned, to form a conductive via in the via hole and a conductive pad on the conductive via and the first passivation layer. FIG. 3D, FIG. 4E and FIG. 5D illustrate views corresponding to some embodiments of act S608.

In accordance with some embodiments of the disclosure, a semiconductor device includes a conductive feature, a first passivation layer, a metal-insulator-metal (MIM), a conductive via, a conductive pad and a second passivation. The first passivation layer is disposed over the conductive feature and exposes the conductive feature. The MIM structure is disposed in the first passivation layer. The conductive via is disposed in the first passivation layer to electrically connect to the conductive feature, and the conductive via has a first surface facing the conductive feature and a first sidewall facing the first passivation layer. A first angle formed between the first surface and the first sidewall is in a range from 95 degrees to 110 degrees. The conductive pad is disposed over the first passivation layer and the conductive via and electrically connected to the conductive via. The second passivation layer is disposed over the conductive pad.

In accordance with some embodiments of the disclosure, a semiconductor device includes a conductive feature, a first passivation layer, a conductive via and a conductive pad. The first passivation layer is disposed on the conductive feature and exposes the conductive feature. The conductive via is disposed in the first passivation layer to electrically connect to the conductive feature, and the conductive via has a first surface facing the conductive feature and a second surface opposite to the first surface. The conductive pad is disposed on the conductive via and the first passivation layer and has a third surface facing the conductive via and the first passivation layer and a fourth surface opposite to the third surface. A minimum distance between the first surface and the fourth surface is a first distance, a maximum distance between the third surface and the fourth surface is a second distance, wherein a ratio of the first distance to the second distance is larger than 0.8.

In accordance with some embodiments of the disclosure, a method of forming a semiconductor device includes the following steps. A first passivation layer is formed on a conductive feature. A via hole is formed in the first passivation layer to expose the conductive feature, wherein an angle formed between a bottom surface and a sidewall of the via hole is in a range from 95 degrees to 110 degrees. A conductive layer is deposited in the via hole and on the first passivation layer. The conductive layer is patterned, to form a conductive via in the via hole and a conductive pad on the conductive via and the first passivation layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a conductive feature;
a first passivation layer over the conductive feature and exposing the conductive feature;
a metal-insulator-metal (MIM) structure in the first passivation layer;
a conductive via, disposed in the first passivation layer to electrically connect to the conductive feature, the conductive via having a first surface facing the conductive feature and a first sidewall facing the first passivation layer, wherein a first angle formed between the first surface and the first sidewall is in a range from 95 degrees to 110 degrees;
a conductive pad, disposed over the first passivation layer and the conductive via and electrically connected to the conductive via; and
a second passivation layer over the conductive pad.

2. The semiconductor structure according to claim 1, wherein the MIM structure comprises a first metal layer, an insulating layer and a second metal layer, the first metal layer and the second metal layer are electrically connected to the conductive via, and the insulating layer is disposed between the first metal layer and the second metal layer.

3. The semiconductor structure according to claim 1, wherein the conductive via further has a second sidewall facing the MIM structure and in contact with the MIM structure.

4. The semiconductor structure according to claim 1, wherein the conductive pad comprises a recessed feature on the conductive via, and a feature of the second passivation layer is disposed in the recessed feature.

5. The semiconductor structure according to claim 4, wherein a width of the recessed feature continuously increases as the recessed feature becomes away from the conductive feature.

6. The semiconductor structure according to claim 4, wherein the recessed feature has a second surface, a second sidewall and a third sidewall opposite to the second sidewall, and a second angle formed between the second surface and the third sidewall is larger than the first angle.

7. The semiconductor structure according to claim 4, wherein the conductive pad has a third surface facing the first passivation layer and a fourth surface opposite to the third surface, a minimum distance formed between the first surface and the second surface is a first distance, a maximum distance formed between the third surface and the fourth surface is a second distance, and a ratio of the first distance to the second distance is larger than 0.8.

8. The semiconductor structure according to claim 1, wherein a surface of the first passivation layer has an inclined portion and a substantially planar portion respectively interfacing with the conductive pad.

9. The semiconductor structure according to claim 1, wherein a surface of the first passivation layer interfacing with the conductive pad is entirely planar.

10. A semiconductor device, comprising:
a conductive feature;
a first passivation layer on the conductive feature and exposing the conductive feature;
a conductive via, disposed in the first passivation layer to electrically connect to the conductive feature, the conductive via having a first surface facing the conductive feature and a second surface opposite to the first surface; and
a conductive pad, disposed on the conductive via and the first passivation layer, having a third surface facing the conductive via and the first passivation layer and a fourth surface opposite to the third surface, a minimum distance between the first surface and the fourth surface being a first distance, a maximum distance between the third surface and the fourth surface being a second distance, wherein a ratio of the first distance to the second distance is larger than 0.8.

11. The semiconductor structure according to claim 10, wherein the fourth surface has a recessed portion and a substantially planar portion, the first distance is formed between the first surface and the recessed portion of the fourth surface, and the second distance is formed between the third surface and the substantially planar portion of the fourth surface.

12. The semiconductor structure according to claim 11, wherein the recessed portion of the fourth surface is disposed between the substantially planar portion of the fourth surface and a surface of the first passivation layer interfacing with the conductive pad.

13. The semiconductor structure according to claim 10, further comprising a metal-insulator-metal (MIM) structure in the first passivation layer and a second passivation layer on the conductive pad, wherein the conductive via is electrically connected to the MIM structure.

14. The semiconductor structure according to claim 10, wherein the ratio is smaller than 1.

15. A method of forming a semiconductor device, comprising:
forming a first passivation layer on a conductive feature;
forming a via hole in the first passivation layer to expose the conductive feature, wherein an angle formed between a bottom surface and a sidewall of the via hole is in a range from 95 degrees to 110 degrees;
depositing a conductive layer in the via hole and on the first passivation layer; and
patterning the conductive layer, to form a conductive via in the via hole and a conductive pad on the conductive via and the first passivation layer.

16. The method according to claim 15, further comprising:
forming a MIM structure on a first sub-passivation layer of the first passivation layer;
forming a second sub-passivation layer of the first passivation layer on the MIM structure; and
forming the via hole in the first sub-passivation layer, the MIM structure and the second sub-passivation layer.

17. The method according to claim 16, further comprising planarizing a top surface of the second sub-passivation layer before forming the via hole.

18. The method according to claim 15, wherein depositing the conductive layer is performed at a temperature in a range from 300° C. to 400° C.

19. The method according to claim 15, wherein depositing the conductive layer is performed at a direct current (DC) power biased with a frequency in a range from 10K W to 30K W and an alternating current power biased with a frequency in a range from 100 W to 1000 W.

20. The method according to claim 15, wherein a minimum thickness of the conductive layer on the conductive feature is a first thickness, a maximum thickness of the conductive layer on the first passivation layer is a second thickness, and a ratio of the first thickness to the second thickness is larger than 0.8.
